(19) United States
(12) Patent Application Publication
(10) Pub. No.: US 2025/0366351 A1
(43) Pub. Date: Nov. 27, 2025

(54) DISPLAY PANEL, ELECTRONIC DEVICE, AND MANUFACTURING METHOD OF THE DISPLAY PANEL

(71) Applicant: Samsung Display Co., Ltd., Yongin-si (KR)

(72) Inventors: HYUNEOK SHIN, Yongin-si (KR); JOONYONG PARK, Yongin-si (KR); DOKEUN SONG, Yongin-si (KR); SUKYOUNG YANG, Yongin-si (KR); Hee Jun YANG, Yongin-si (KR)

(21) Appl. No.: 19/080,484

(22) Filed: Mar. 14, 2025

(30) Foreign Application Priority Data
May 21, 2024 (KR) 10-2024-0065976

(51) Int. Cl. H10K 59/80; H10K 59/12; H10K 59/122

(52) U.S. Cl. CPC H10K 59/873; H10K 59/1201; H10K 59/122

(57) ABSTRACT

A display panel includes: a base layer; a circuit layer on the base layer; a light-emitting element layer on the circuit layer; and an encapsulation layer on the light-emitting element layer, wherein the light-emitting element layer includes a conductive pattern on the circuit layer, a first electrode on the conductive pattern, and a light-emitting pattern on the first electrode, and the encapsulation layer includes a first inorganic encapsulation film surrounding the conductive pattern in a plan view.

### CROSS-REFERENCE TO RELATED APPLICATION

The present application claims priority to and the benefit of Korean Patent Application No. 10-2024-0065976, filed on May 21, 2024, in The Korean Intellectual Property Office, the entire disclosure of which is incorporated herein by reference.

### BACKGROUND

Aspects of some embodiments of the present disclosure herein relate to a display panel, an electronic device including the same, and a manufacturing method thereof, and for example, to a display panel capable of providing high resolution and having relatively improved reliability and processability and a manufacturing method thereof.

Display panels are used in various multimedia devices such as televisions, mobile phones, tablet computers, and game consoles to provide image information to a user. Display panels may include light-emitting elements and pixel circuits for driving the light-emitting elements. The light-emitting elements included in the display panel emit light and generate images according to a voltage applied from the pixel circuit. Development of a patterning method for the light-emitting element may be utilized in order to provide high resolution and relatively improve reliability.

The above information disclosed in this Background section is only for enhancement of understanding of the background and therefore the information discussed in this Background section does not necessarily constitute prior art.

### SUMMARY

Aspects of some embodiments of the present disclosure include a display panel which provides high resolution and has relatively improved reliability.

Aspects of some embodiments of the present disclosure may also include a manufacturing method of a display panel having relatively improved processability and reliability.

According to some embodiments of the present disclosure, a display panel includes a base layer, a circuit layer on the base layer, a light-emitting element layer on the circuit layer, and an encapsulation layer on the light-emitting element layer, wherein the light-emitting element layer includes a conductive pattern on the circuit layer, a first electrode on the conductive pattern, and a light-emitting pattern on the first electrode, and the encapsulation layer includes a first inorganic encapsulation film surrounding the conductive pattern in a plan view.

According to some embodiments, the light-emitting element layer may further include a pixel-defining film between the circuit layer and the first inorganic encapsulation film, and the pixel-defining film may cover an upper surface of the circuit layer, which is exposed because the conductive pattern is not located thereon, and a side surface of the conductive pattern.

According to some embodiments, the pixel-defining film may extend covering from the side surface of the conductive pattern to a side surface of the first electrode.

According to some embodiments, the light-emitting element layer may further include a second electrode on the light-emitting pattern.

According to some embodiments, the light-emitting element layer may further include a capping electrode directly on and electrically connected to the second electrode, and the capping electrode may include transparent conductive oxide (TCO).

According to some embodiments, the capping electrode may include indium zinc oxide (IZO) or indium tin oxide (ITO).

According to some embodiments, the encapsulation layer may further include an auxiliary electrode covering the capping electrode and the first inorganic encapsulation film and arranged in an integrated form, the capping electrode comprises a plurality of capping electrodes, the plurality of capping electrodes may be electrically connected to each other by the auxiliary electrode, and the auxiliary electrode may include transparent conductive oxide (TCO).

According to some embodiments, the encapsulation layer may further include an organic encapsulation film on the auxiliary electrode, and a second inorganic encapsulation film on the organic encapsulation film.

According to some embodiments, in a plan view, the conductive pattern, the first electrode, the light-emitting pattern, and the second electrode may overlap.

According to some embodiments, the first inorganic encapsulation film may cover a side surface of the conductive pattern, a side surface of the first electrode, and a side surface of the light-emitting pattern.

According to some embodiments, the conductive pattern may include a first conductive layer on the circuit layer and a second conductive layer on the first conductive layer, and a side surface of the second conductive layer may protrude further than a side surface of the first conductive layer.

According to some embodiments, the first conductive layer may include aluminum (Al), and the second conductive layer may include titanium (Ti).

According to some embodiments, the first electrode may include a first layer on the conductive pattern and a second layer on the first layer, the first layer may include silver (Ag) or aluminum (Al), and the second layer may include indium tin oxide (ITO) or indium zinc oxide (IZO).

According to some embodiments of the present disclosure, an electronic device includes a display module, a window on the display module, and a housing under the display module, the display module includes a base layer including a plurality of light-emitting regions and a non-light-emitting region surrounding the plurality of light-emitting regions, a light-emitting element layer including a conductive pattern in the plurality of light-emitting regions, a light-emitting element on the conductive pattern, and a pixel-defining film in the non-light-emitting region and defining the plurality of light-emitting regions, and an encapsulation layer including an inorganic encapsulation film in the non-light-emitting region, and an auxiliary electrode integrally in the plurality of light-emitting regions and the non-light-emitting region and electrically connected to the light-emitting element, wherein the conductive pattern includes a first conductive pattern on the base layer and a second conductive pattern on the first conductive pattern, and a side surface of the second conductive pattern protrudes further than a side surface of the first conductive pattern.

According to some embodiments of the present disclosure, a manufacturing method of a display panel includes providing a preliminary display panel including a circuit layer, a conductive pattern on the circuit layer, and a light-emitting element on the conductive pattern, forming an inorganic encapsulation film to surround the conductive pattern and the light-emitting element in a plan view, and forming an auxiliary electrode on the light-emitting element and the inorganic encapsulation film.

According to some embodiments, the providing of the preliminary display panel may include forming a first electrode, a light-emitting pattern, and a second electrode on the conductive pattern.

According to some embodiments, the providing of the preliminary display panel may further include forming a capping electrode on the second electrode.

According to some embodiments, the providing of the preliminary display panel may further include forming a pixel-defining film defining a pixel region on the circuit layer, and the pixel-defining film may be formed to cover at least a side surface of the first electrode.

According to some embodiments, the auxiliary electrode may be integrally formed.

According to some embodiments, the conductive pattern may include a first conductive pattern on the circuit layer and a second conductive pattern on the first conductive pattern, and a side surface of the second conductive pattern may be formed to protrude further than a side surface of the first conductive pattern.

### BRIEF DESCRIPTION OF THE DRAWINGS

The accompanying drawings are included to provide a further understanding of embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1A is an assembled perspective view of an electronic device according to some embodiments of the present disclosure;

FIG. 1B is an exploded perspective view of an electronic device according to some embodiments of the present disclosure;

FIG. 2A is an assembled perspective view of an electronic device according to some embodiments of the present disclosure;

FIG. 2B is an exploded perspective view of an electronic device according to some embodiments of the present disclosure;

FIG. 3 is a cross-sectional view of a display module according to some embodiments of the present disclosure;

FIG. 4 is a plan view of a display panel according to some embodiments of the present disclosure;

FIG. 5 is an enlarged plan view of a portion of an active region according to some embodiments of the present disclosure;

FIG. 6 is a cross-sectional view of a display panel according to some embodiments of the present disclosure;

FIGS. 7A to 7G each are a cross-sectional view illustrating a step of a manufacturing method of a display panel according to some embodiments of the present disclosure; and

FIGS. 8A and 8B each are a graph showing an evaluation result of moisture permeation characteristics of a capping electrode according to some embodiments of the present disclosure.

### DETAILED DESCRIPTION

Aspects of some embodiments of the present disclosure may be variously modified and have various forms, but specific embodiments will be illustrated in the drawings and described in detail in the description. However, this is not intended to limit the present disclosure to a specific disclosed form, and it should be understood that all changes, equivalents, and alternatives included in the spirit and scope of the present disclosure are included.

In this specification, it will be understood that when an element (or a region, a layer, a portion, or the like) is referred to as being “on”, “connected to” or “coupled to” another element, it may be directly located on, connected or coupled to the other element, or an intervening element may be located therebetween.

As used herein, the wording “directly located” may mean that there is no layer, film, region, plate, etc. added between a portion such as a layer, film, region, or plate and another portion. For example, “directly located” may mean placing two layers or two members without using an additional member such as an adhesive member therebetween.

Like reference numerals or symbols refer to like elements. Also, in the drawings, the thicknesses, ratios, and dimensions of the elements are exaggerated for effective description of the technical contents.

The term “and/or” includes all of one or more combinations which may be defined by related elements.

Although the terms first, second, etc. may be used herein to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well unless the context clearly indicates otherwise.

In addition, terms such as “below”, “on lower side”, “above”, and “on upper side” may be used herein to describe the relationships of the elements illustrated in the drawings. These terms have relative concepts and are described on the basis of the directions indicated in the drawings. As used herein, the wording “located on” may represent not only being located on an upper portion of any one member but also being located on a lower portion thereof.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, aspects of some embodiments of the present disclosure will be described in more detail with reference to the drawings.

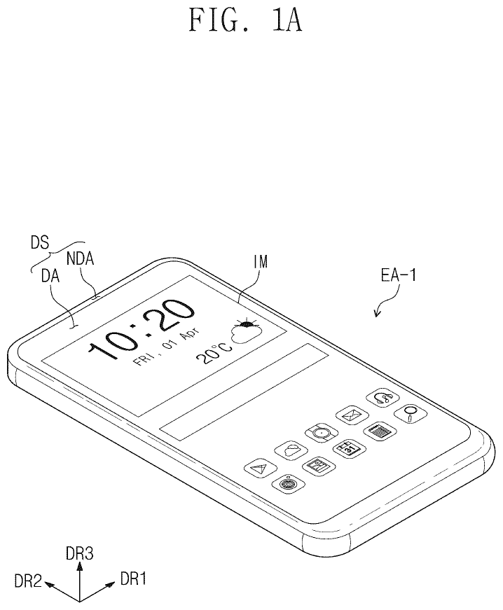

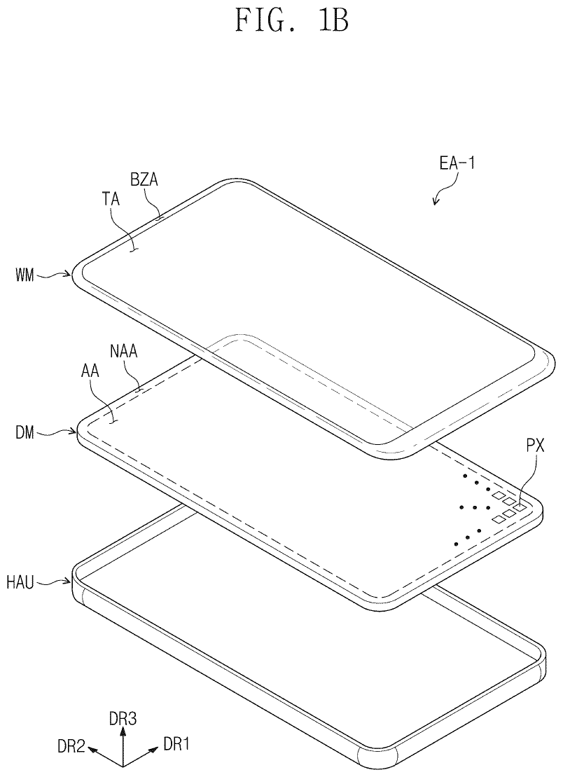

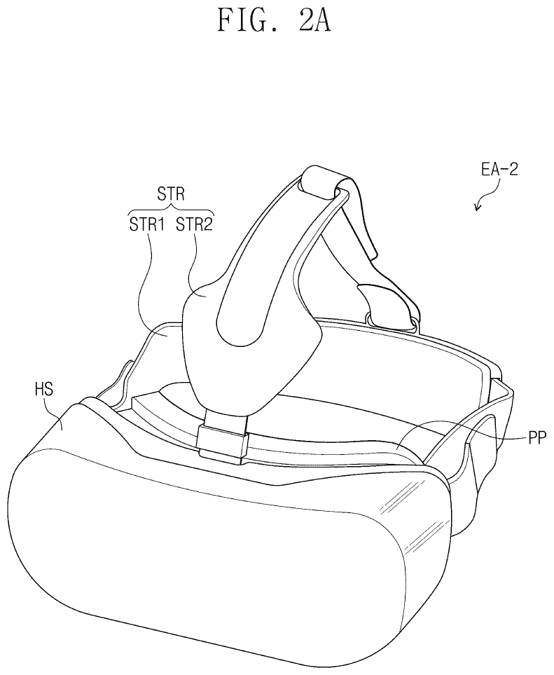

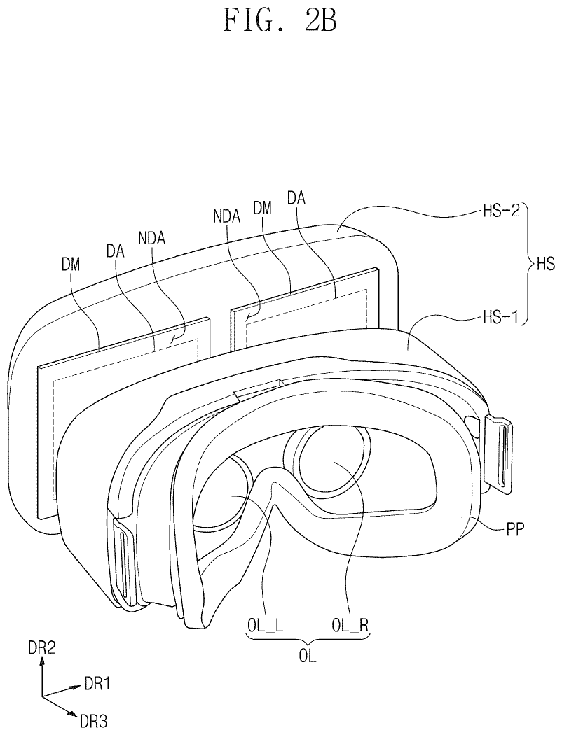

FIG. 1A is an assembled perspective view of an electronic device EA-1 according to some embodiments of the present disclosure. FIG. 1B is an exploded perspective view of the electronic device EA-1 according to some embodiments of the present disclosure. FIG. 2A is an assembled perspective view of an electronic device EA-2 according to some embodiments of the present disclosure. FIG. 2B is an exploded perspective view of the electronic device EA-2 according to some embodiments of the present disclosure.

The electronic devices EA-1 and EA-2 according to some embodiments may be activated in response to an electrical signal. For example, the electronic devices EA-1 and EA-2 may be each a large-sized electronic device such as a television, a monitor, or an outdoor billboard. In addition, the electronic devices EA-1 and EA-2 may be each a small- or medium-sized electronic device such as a personal computer, a laptop, a personal digital assistant, a car navigation device, a game console, a mobile phone, a tablet PC, or a camera. These are examples, and embodiments according to the present disclosure are not limited thereto. FIGS. 1A and 1B illustrate that the electronic device EA-1 is a mobile phone. FIGS. 2A and 2B illustrate that the electronic device EA-2 is a wearable display device.

The electronic devices EA-1 and EA-2 according to some embodiments may be rigid or flexible. The term “flexible” means bendable characteristics. For example, flexible electronic devices EA-1 and EA-2 may include a curved device, a rollable device, or a foldable device.

FIG. 1A and subsequent drawings illustrate a first direction DR1, a second direction DR2, and a third direction DR3, and directions indicated by the first to third directions DR1, DR2, and DR3 described herein may have relative concepts and thus may be changed into other directions. In addition, opposite directions of the directions indicated by the first to third directions DR1, DR2, and DR3 may be also described as first to third directions and denoted as the same reference numerals or symbols.

Referring to FIG. 1A, the electronic device EA-1 according to some embodiments may include a display surface DS that is defined by a first direction DR1 and a second direction DR2 crossing the first direction DR1. The electronic device EA-1 may provide an image IM to a user through the display surface DS. The electronic device EA-1 according to some embodiments may display the image IM in a third direction DR3 on the display surface DS parallel to each of the first direction DR1 and the second direction DR2. Herein, a front surface (or an upper surface) and a rear surface (or a lower surface) of each element are defined on the basis of a direction in which the image IM is displayed. The front surface and the rear surface may be opposed to each other in the third direction DR3, and a normal direction of each of the front surface and the rear surface may be parallel to the third direction DR3.

According to some embodiments, the display surface DS may include a display region DA and a non-display region NDA adjacent to (e.g., in a periphery or outside a footprint of) the display region DA. The non-display region NDA may be a region in which the image IM is not displayed. However, embodiments according to the present disclosure are not limited thereto, and according to some embodiments the non-display region NDA may be omitted.

The electronic device EA-1 according to some embodiments may sense an external input applied from the outside. The external input may include inputs in various forms provided from outside the electronic device EA-1. For example, the external input may include not only a contact from a part of a body, such as a user's hand, but also an external input (for example, hovering) applied close to or adjacent at a distance from the electronic device EA-1. In addition, the external input may be in various forms such as force, pressure, temperature, and light.

The electronic device EA-1 according to some embodiments may further include various electronic modules. For example, an electronic module may include at least any one among a camera, a speaker, a photosensitive sensor, and a thermal sensor. The electronic module may sense a received external subject through the display surface DS or provide, to the outside, a sound signal such as a voice through the display surface DS. The electronic module may include a plurality of components, and is not limited to any one embodiment.

Referring to FIG. 1B, the electronic device EA-1 according to some embodiments may include a display module DM and a window WM located on the display module DM. The window WM may be located on at least one of an upper portion or a lower portion of the display module DM. FIG. 1B illustrates that the window WM is located on the upper portion of the display module DM.

In addition, the electronic device EA-1 according to some embodiments may further include an electronic module located on a lower side of the display module DM. For example, the electronic module may include a camera module.

In addition, according to some embodiments, the electronic device EA-1 may further include a polarizing film and/or an adhesive layer located between the display module DM and the window WM. In addition, according to some embodiments, the electronic device EA-1 may further include a lower functional layer located on the lower side of the display module DM.

The electronic device EA-1 according to some embodiments may further include a housing HAU in which the display module DM, a lower functional layer, and the like are accommodated. The housing HAU may be coupled to the window WM to form an exterior of the electronic device EA-1. The housing HAU may include a material having relatively high rigidity. For example, the housing HAU may include a plurality of frames and/or plates composed of glass, plastic, or metal. The display module DM may be accommodated in an accommodation space and protected from an external impact.

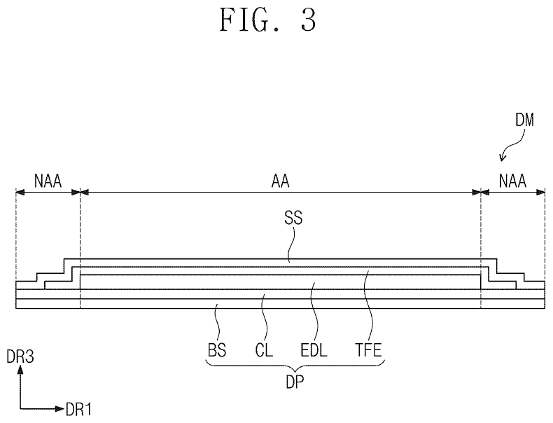

The display module DM according to some embodiments may display the image IM (see FIG. 1A) and transmit/receive information about an external input in response to an electrical signal. The display module DM may include a display panel DP (see FIG. 3) and a sensor layer SS (see FIG. 3) located on the display panel DP (see FIG. 3).

The display module DM may include an active region AA and a peripheral region NAA. The active region AA may be a region in which the image IM (see FIG. 1A) is provided. A pixel PX may be located in the active region AA. The peripheral region NAA may be adjacent to the active region AA. The peripheral region NAA may surround the active region AA. A driving circuit, a driving line, or the like for driving the active region AA may be located in the peripheral region NAA.

The display module DM may include a plurality of pixels PX. The pixels PX may each display light in response to an electrical signal. Light displayed by the pixels PX may provide the image IM (see FIG. 1A). The pixels PX may each include a display element. For example, the display element may be an organic light-emitting element, an inorganic light-emitting element, an organic-inorganic light-emitting element, a micro-LED, a nano-LED, a quantum dot light-emitting element, an electrophoretic element, an electrowetting element, etc.

The window WM may entirely cover an upper surface of the display module DM. The window WM may have a shape corresponding to a shape of the display module DM. The window WM may have flexibility which allows the window WM to be deformed according to deformation such as folding or bending of the electronic device EA-1. The window WM may function to protect the display module DM from an external impact.

The window WM may include a transmission region TA and a bezel region BZA. The transmission region TA may overlap at least a portion of the active region AA of the display module DM. The transmission region TA may be an optically transparent region. For example, a transmittance of the transmission region TA with respect to a wavelength of a visible light region may be at least 90% (or about 90%). The image IM (see FIG. 1A) may be provided to a user through the transmission region TA, and a user may receive information through the image IM (see FIG. 1A).

The bezel region BZA may be a region having a relatively low light transmittance compared to the transmission region TA. The bezel region BZA may define a shape of the transmission region TA. The bezel region BZA may have a color. The bezel region BZA may cover the peripheral region NAA of the display module DM and prevent or reduce visibility of the peripheral region NAA from the outside. This is an example, and the bezel region BZA may be omitted in the window WM according to some embodiments.

The electronic device EA-2 according to some embodiments illustrated in FIGS. 2A and 2B may be activated in response to an electrical signal and may be a wearable device. The wearable device may be a device which is worn on a user's body and may include a head mounted display (HMD) which provides extended reality (XR), virtual reality (VR), augmented reality (AR), or mixed reality (MR). FIGS. 2A and 2B illustrate that the electronic device EA-2 is a head mounted display, but embodiments according to the present disclosure are not limited thereto.

The electronic device EA-2 according to some embodiments illustrated in FIGS. 2A and 2B is a display device which is worn on a user's head. The electronic device EA-2 may provide an image while an actual peripheral vision of a user is blocked. A user wearing the electronic device EA-2 may be more easily immersed in virtual reality.

The electronic device EA-2 may include a body part HS, a strap part STR, a cushion part PP, and a display module DM. According to some embodiments, the electronic device EA-2 may include various sensors, a camera, and the like.

The body part HS may be worn on a user's head. The display module DM for displaying an image, an acceleration sensor, and the like may be accommodated inside the body part HS. The acceleration sensor may sense a movement of the user and transmit a signal to the display module DM. Accordingly, the display module DM may provide an image corresponding to a change in the user's eyeline. Thus, the user may experience realistic virtual reality. The description made with reference to FIG. 1B may be equally applied to the display module DM. In addition, a component of the display module DM included in the electronic device EA-2 according to some embodiments may be provided to include a different component from that illustrated in FIG. 1B in accordance with characteristics of a wearable device.

Components having various functions may be accommodated in the body part HS in addition to the above components. For example, an operation part for adjusting sound volume, brightness of a screen, or the like may be additionally located on an outer portion of the body part HS. The operation part may be provided in a form of a physical button, a touch sensor, or the like. In addition, a proximity sensor for determining whether a user is wearing the electronic device or not may be accommodated in the body part HS. In addition, an external display panel may be further located in the body part HS.

The body part HS may be separated into a body portion HS-1 and a cover portion HS-2. FIG. 2B illustrates a form in which the body portion HS-1 and the cover portion HS-2 are separated from each other, but embodiments according to the present disclosure are not limited thereto. For example, the body portion HS-1 and the cover portion HS-2 may be integrally provided and may not be separated from each other.

Display modules DM may be located between the body portion HS-1 and the cover portion HS-2. The display modules DM may each provide an image through an active region AA. The display modules DM may each include a peripheral region NAA surrounding the active region AA. According to some embodiments, the peripheral region NAA may be located on only one side of the active region AA or omitted.

FIG. 2B illustrates that a left eye image and a right eye image are respectively provided by the display modules DM separated from each other, but embodiments according to the present disclosure are not limited thereto. For example, the left eye image and the right eye image may be displayed through one display module. The display modules DM may be driven by separate driving units. However, embodiments according to the present disclosure are not limited thereto, and the display modules DM may be driven by one driving unit. The display modules DM generate an image corresponding to inputted image data.

The strap part STR may be coupled to the body part HS to allow the body part HS to be easily worn on a user. The strap part STR may include a main strap STR1 and an upper strap STR2.

The main strap STR1 may be worn along a circumference of a user's head. The main strap STR1 may fix the body part HS to the user such that the body part HS may be tightly fitted to the user's head. The upper strap STR2 may connect the body part HS and the main strap STR1 along an upper portion of the user's head. The upper strap STR2 may prevent or reduce instances of the body part HS slipping down. In addition, the upper strap STR2 may disperse weight of the body part HS, thereby providing relatively improved wearing comfort to the user.

The strap part STR may be changed into various forms in addition to the form shown in FIG. 2A if the strap part STR is capable of fixing the body part HS to a user. For example, according to some embodiments of the present disclosure, the upper strap STR2 may be omitted. In addition, according to some embodiments of the present disclosure, the strap part STR may be changed into various forms such as a helmet coupled to the body part HS, temples of a pair of glasses coupled to the body part HS, or the like.

The cushion part PP may be located between the body part HS and a user's head. The cushion part PP may be formed of a material that may be freely deformed. For example, the cushion part PP may be formed of a polymer resin (for example, polyurethane, polycarbonate, polypropylene, and polyethylene), or formed of rubber solution, a urethane-based material, or a sponge formed by foam molding an acrylic material. However, a material of the cushion part PP is not limited thereto.

The cushion part PP may allow the body part HS to be tightly fitted to a user, thereby providing relatively improved wearing comfort to the user. The cushion part PP may be detached from the body part HS. According to some embodiments of the present disclosure, the cushion part PP may be omitted.

An optical system OL may be located inside the body portion HS-1 of the body part HS. The optical system OL may enlarge an image provided from the display modules DM. The display modules DM may each display an image in a third direction DR3 through the active region AA parallel to a first direction DR1 and a second direction DR2 crossing the first direction DR1. The optical system OL may be spaced apart from the display modules DM in the third direction DR3. The optical system OL may be located between the display modules DM and a user's eye. The optical system OL may include a right eye optical system OL_R and a left eye optical system OL_L. The left eye optical system OL_L may enlarge an image and provide the enlarged image to a left pupil of the user, and the right eye optical system OL_R may enlarge an image and provide the enlarged image to a right pupil of the user.

The left eye optical system OL_L and the right eye optical system OL_R may be spaced apart from each other in the first direction DR1. A distance between the right eye optical system OL_R and the left eye optical system OL_L may be adjusted to correspond to a distance between two eyes of a user. In addition, a distance between the optical system OL and the display modules DM may be adjusted according to a user's eyesight.

The optical system OL may be a convex aspheric lens. For example, the optical system OL may be a pancake lens, but is not particularly limited thereto. According to some embodiments, it is described that the left eye optical system OL_L and the right eye optical system OL_R each include only one lens, but embodiments according to the present disclosure are not limited thereto. For example, the left eye optical system OL_L and the right eye optical system OL_R may each include a plurality of lenses.

The electronic device EA-2 according to some embodiments as illustrated in FIGS. 2A and 2B may further include a window located on the display module DM. The window may include a base substrate, a reflection reduction layer, and the like.

The display module DM included in the electronic devices EA-1 and EA-2 according to some embodiments may have high resolution characteristics. For example, the display module DM according to some embodiments may have display quality of ultra-high resolution of at least 3000 ppi (or about 3000 ppi).

FIG. 3 is a cross-sectional view of a display module DM according to some embodiments of the present disclosure.

Referring to FIG. 3, the display module DM may include a display panel DP and a sensor layer SS located on the display panel DP. An active region AA and a peripheral region NAA shown in FIG. 3 may correspond to the active region AA and the peripheral region NAA shown in FIG. 1B.

The display panel DP may include a base layer BS, a circuit layer CL, a light-emitting element layer EDL, and an encapsulation layer TFE.

The base layer BS may be a member that provides a base surface on which the circuit layer CL is located. The base layer BS may be a rigid substrate or a flexible substrate capable of being bent, folded, or rolled. The base layer BS may be a glass substrate, a metal substrate, a polymer substrate, or the like. However, embodiments according to the present disclosure are not limited thereto, and the base layer BS may be an inorganic layer, an organic layer, or a composite material layer.

The circuit layer CL may be located on the base layer BS. The circuit layer CL may include an insulating layer, a semiconductor pattern, a conductive pattern, a signal line, and the like. An insulating layer, a semiconductor layer, and a conductive layer may be formed on the base layer BS by coating, depositing, or the like, and then the insulating layer, the semiconductor layer, and the conductive layer may be selectively patterned through a photolithography process and an etching process performed multiple times. Thereafter, a semiconductor pattern, a conductive pattern, and a signal line included in the circuit layer CL may be formed.

The light-emitting element layer EDL may be located on the circuit layer CL. The light-emitting element layer EDL may include a light-emitting element. For example, the light-emitting element may include an organic light-emitting material, an inorganic light-emitting material, an organic-inorganic light-emitting material, a quantum dot, a quantum rod, a micro-LED, or a nano-LED.

The encapsulation layer TFE may be located on the light-emitting element layer EDL. The encapsulation layer TFE may cover the light-emitting element layer EDL. The encapsulation layer TFE may protect the light-emitting element layer EDL from moisture, oxygen, and foreign substances such as dust particles.

The sensor layer SS may be located on the display panel DP. The sensor layer SS may sense an external input applied from the outside. The external input may be a user's input. The user's input may include external inputs in various forms such as a part of a user's body, light, heat, a pen, or pressure. For example, the sensor layer SS may sense the external input using a capacitive method. According to the present disclosure, an operating method of the sensor layer SS is not particularly limited, and the sensor layer SS may sense the external input using an electromagnetic induction method or a pressure sensing method.

The sensor layer SS may be formed on the display panel DP through a continuous process. In this case, the sensor layer SS may be directly located on the display panel DP. Here, the wording “directly located” may mean that a third component is not located between the sensor layer SS and the display panel DP. That is, a separate adhesive member may not be located between the sensor layer SS and the display panel DP. For example, the sensor layer SS may be directly located on the encapsulation layer TFE of the display panel DP. In addition, the sensor layer SS and the display panel DP may be coupled to each other through an adhesive member. The adhesive member may include typical adhesive agent or bonding agent.

The sensor layer SS may have a multi-layered structure. The sensor layer SS may include a single-layered or multi-layered conductive layer. The sensor layer SS may include a single-layered or multi-layered insulating layer.

An optical layer may be further located on the sensor layer SS. The optical layer may be directly located on the sensor layer SS. The optical layer may be formed on the sensor layer SS through a continuous process. The optical layer may reduce reflectance for external light incident from outside the display module DM. The optical layer may include a polarizing layer or a color filter layer.

According to some embodiments, the sensor layer SS may be omitted, and the optical layer may be directly located on the display panel DP. According to some embodiments, positions of the sensor layer SS and the optical layer may be interchanged.

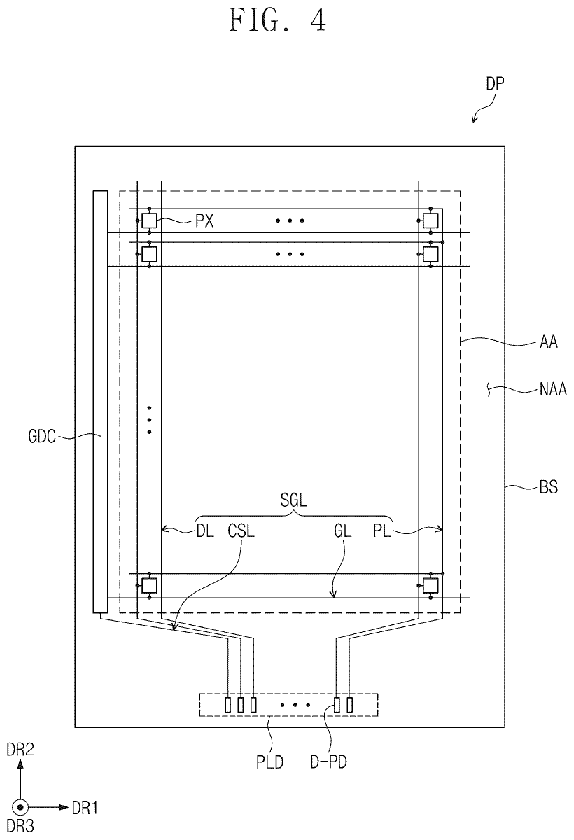

FIG. 4 is a plan view of a display panel DP according to some embodiments of the present disclosure.

Referring to FIG. 4, the display panel DP may include a base layer BS divided into an active region AA and a peripheral region NAA.

The display panel DP may include pixels PX located in the active region AA and signal lines SGL electrically connected to the pixels PX. The display panel DP may include a driving circuit GDC and a pad part PLD located in the peripheral region NAA.

The pixels PX may be arranged in a first direction DR1 and a second direction DR2. The pixels PX may include a plurality of pixel rows extending in the first direction DR1 and arranged in the second direction DR2, and a plurality of pixel columns extending in the second direction DR2 and arranged in the first direction DR1.

The signal lines SGL may include gate lines GL, data lines DL, a power line PL, and a control signal line CSL. The gate lines GL may be each connected to a corresponding pixel among the pixels PX, and the data lines DL may be each connected to a corresponding pixel among the pixels PX. The power line PL may be electrically connected to the pixels PX. The control signal line CSL may be connected to the driving circuit GDC and provide control signals to the driving circuit GDC.

The driving circuit GDC may include a gate driving circuit. The gate driving circuit may generate gate signals and sequentially output generated gate signals to the gate lines GL. The gate driving circuit may further output another control signal to a pixel driving circuit.

The pad part PLD may be a portion to which a flexible circuit board is connected. The pad part PLD may include pixel pads D-PD, and the pixel pads D-PD may be pads for connecting a flexible circuit board to the display panel DP. The pixel pads D-PD may be each connected to a corresponding signal line among the signal lines SGL. The pixel pads D-PD may be connected to corresponding pixels PX via the signal lines SGL. In addition, any one pixel pad among the pixel pads D-PD may be connected to the driving circuit GDC.

In addition, the pad part PLD may further include input pads. The input pads may be pads for connecting a flexible circuit board to the sensor layer SS (see FIG. 3). However, embodiments of the present disclosure are not limited thereto, and the input pads may be located on the sensor layer SS (see FIG. 3) and connected to a circuit board separate from the pixel pads D-PD. Alternatively, the sensor layer SS (see FIG. 3) may be omitted, and the input pads may not be further included.

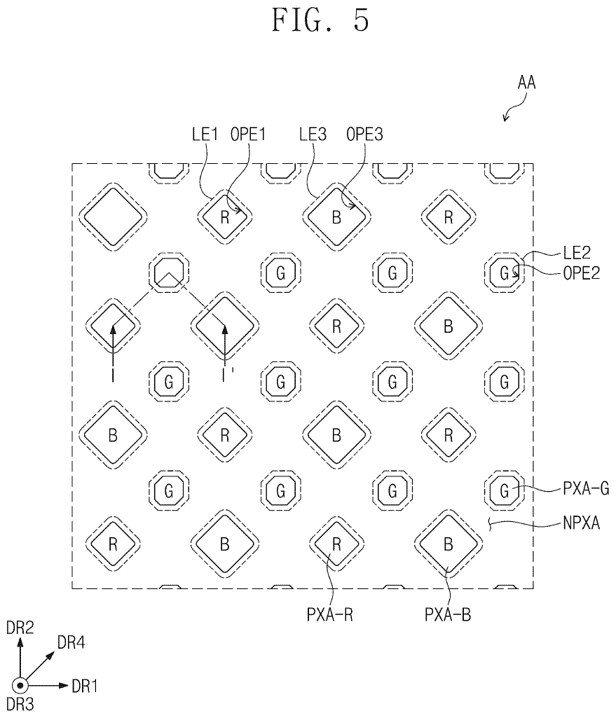

FIG. 5 is an enlarged plan view of a portion of an active region AA according to some embodiments of the present disclosure. FIG. 5 illustrates an enlarged plan view of the active region AA of the display module DM (see FIG. 1B) viewed from above the display surface DS (see FIG. 1A).

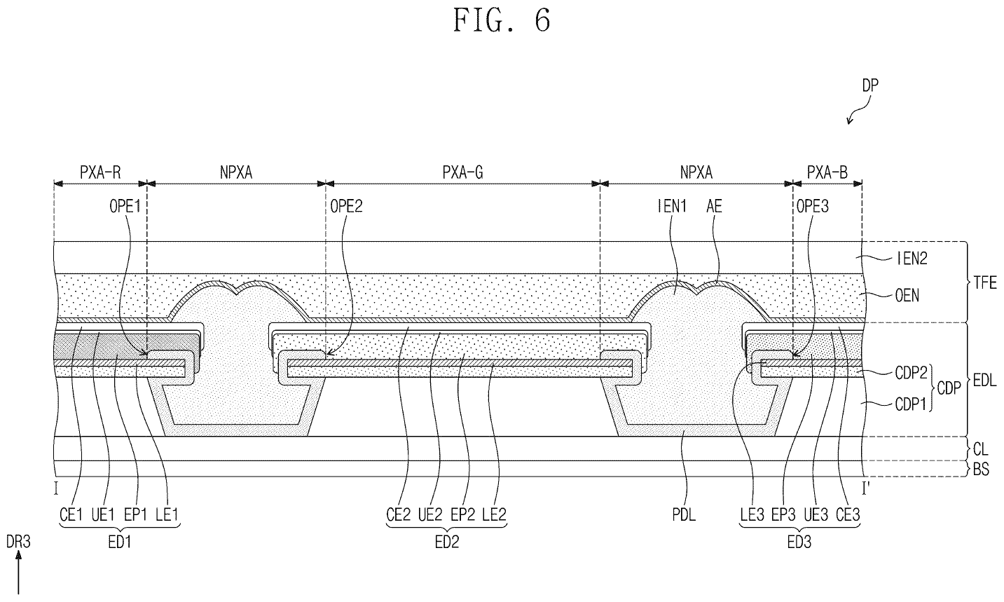

Referring to FIG. 5, the active region AA may include first to third light-emitting regions PXA-R, PXA-G, and PXA-B and a non-light-emitting region NPXA surrounding the first to third light-emitting regions PXA-R, PXA-G, and PXA-B. The first to third light-emitting regions PXA-R, PXA-G, and PXA-B may respectively correspond to regions in which light provided from light-emitting elements ED1, ED2, and ED3 (see FIG. 6) is emitted.

For convenience of description, FIG. 5 illustrates only lower electrodes LE1, LE2, and LE3 among components of the light-emitting elements ED1, ED2, and ED3 (see FIG. 6). The first to third light-emitting regions PXA-R, PXA-G, and PXA-B may be divided according to a color of light emitted toward the outside of the display module DM (see FIG. 1B).

The first to third light-emitting regions PXA-R, PXA-G, and PXA-B may respectively provide first to third color light having different colors. For example, the first color light may be red light, the second color light may be green light, and the third color light may be blue light. However, examples of the first to third color light are not necessarily limited to the above examples.

The first to third light-emitting regions PXA-R, PXA-G, and PXA-B may be each defined as a region exposed by a corresponding light-emitting opening OPE1, OPE2, or OPE3 in an upper surface of a corresponding lower electrode LE1, LE2, or LE3. The light-emitting openings OPE1, OPE2, and OPE3 may be defined by a pixel-defining film PDL (see FIG. 6) partially covering the lower electrodes LE1, LE2, and LE3.

Specifically, the first light-emitting region PXA-R may be defined as a region exposed by a first light-emitting opening OPE1 in an upper surface of a first lower electrode LE1. In addition, the second light-emitting region PXA-G may be defined as a region exposed by a second light-emitting opening OPE2 in an upper surface of a second lower electrode LE2. In addition, the third light-emitting region PXA-B may be defined as a region exposed by a third light-emitting opening OPE3 in an upper surface of a third lower electrode LE3.

The non-light-emitting region NPXA may set boundaries of the first to third light-emitting regions PXA-R, PXA-G, and PXA-B and prevent or reduce color mixing between the first to third light-emitting regions PXA-R, PXA-G, and PXA-B.

The first to third light-emitting regions PXA-R, PXA-G, and PXA-B may be each provided in plurality to have an arrangement form and be repeatedly arranged in the active region AA.

For example, referring to FIG. 5, a plurality of first light-emitting regions PXA-R and a plurality of third light-emitting regions PXA-B may be alternately arranged along a first direction DR1 and constitute a “first group”. In addition, second light-emitting regions PXA-G may be arranged along the first direction DR1 and constitute a “second group”. The “first group” and the “second group” may be each provided in plurality, and “first groups” and “second groups” may be alternately arranged along a second direction DR2.

One second light-emitting region PXA-G may be arranged to be spaced apart from one first light-emitting region PXA-R or one third light-emitting region PXA-B in a fourth direction DR4. The fourth direction DR4 may be defined as a direction between the first direction DR1 and the second direction DR2 on a plane defined by the first direction DR1 and the second direction DR2.

As shown in FIG. 5, the first to third light-emitting regions PXA-R, PXA-G, and PXA-B may have a PENTILE™ arrangement form. However, the arrangement form of the first to third light-emitting regions PXA-R, PXA-G, and PXA-B shown in FIG. 5 is an example, and the first to third light-emitting regions PXA-R, PXA-G, and PXA-B may be arranged in various forms without being limited thereto. For example, the first to third light-emitting regions PXA-R, PXA-G, and PXA-B may have a stripe arrangement form or a Diamond Pixel™ arrangement form.

The first to third light-emitting regions PXA-R, PXA-G, and PXA-B may each have various shapes in a plan view. For example, the first to third light-emitting regions PXA-R, PXA-G, and PXA-B may each have a polygonal shape, a circular shape, an elliptical shape, or the like. FIG. 5 illustrates the first light-emitting region PXA-R and the third light-emitting region PXA-B having a quadrangular shape (or a rhombic shape) and the second light-emitting region PXA-G having an octagonal shape in a plan view.

In a plan view, the first to third light-emitting regions PXA-R, PXA-G, and PXA-B may have the same shape, or at least a portion thereof may have different shapes. FIG. 5 illustrates the first light-emitting region PXA-R and the third light-emitting region PXA-B having the same shape and the second light-emitting region PXA-G having a shape different from that of each of the first light-emitting region PXA-R and the third light-emitting region PXA-B in a plan view.

At least a portion of the first to third light-emitting regions PXA-R, PXA-G, and PXA-B may have different area sizes in a plan view. Specifically, an area size of the first light-emitting region PXA-R in which red light is emitted may be larger than an area size of the second light-emitting region PXA-G in which green light is emitted and smaller than an area size of the third light-emitting region PXA-B in which blue light is emitted. However, size relationship between area sizes of the first to third light-emitting regions PXA-R, PXA-G, and PXA-B is not limited thereto according to a color of emitted light and may vary according to a design of the display module DM (see FIG. 1B). For example, the first to third light-emitting regions PXA-R, PXA-G, and PXA-B may have the same area size in a plan view.

A shape, area size, and arrangement, in a plan view, of the first to third light-emitting regions PXA-R, PXA-G, and PXA-B of the display module DM (see FIG. 1B) of the present disclosure may be variously designed according to a color of emitted light or a size and configuration of the display module DM (see FIG. 1B) and are not limited to the embodiments illustrated in FIG. 5.

FIG. 6 is a cross-sectional view of a display panel DP according to some embodiments of the present disclosure.

FIG. 6 schematically illustrates a cross-section taken along line I-I′ of FIG. 5. That is, FIG. 6 may illustrate a cross-section of the first to third light-emitting regions PXA-R, PXA-G, and PXA-B and the non-light-emitting region NPXA surrounding the first to third light-emitting regions PXA-R, PXA-G, and PXA-B of FIG. 5. The first to third light-emitting regions PXA-R, PXA-G, and PXA-B may respectively correspond to regions in which light provided from light-emitting elements ED1, ED2, and ED3 is emitted.

Referring to FIG. 6, the display panel DP may include a base layer BS, a circuit layer CL located on the base layer BS, a light-emitting element layer EDL located on the circuit layer CL, and an encapsulation layer TFE located on the light-emitting element layer EDL. The above descriptions made with reference to FIG. 3 may be equally applied to the base layer BS and the circuit layer CL of FIG. 6. The light-emitting element layer EDL and the encapsulation layer TFE will be described in detail with reference to FIG. 6.

The light-emitting element layer EDL may include the light-emitting elements ED1, ED2, and ED3, a conductive pattern CDP, and a pixel-defining film PDL.

The light-emitting elements ED1, ED2, and ED3 may include a first light-emitting element ED1, a second light-emitting element ED2, and a third light-emitting element ED3. The first light-emitting element ED1 may include a first lower electrode LE1, a first light-emitting pattern EP1, a first upper electrode UE1, and a first capping electrode CE1. The second light-emitting element ED2 may include a second lower electrode LE2, a second light-emitting pattern EP2, a second upper electrode UE2, and a second capping electrode CE2. The third light-emitting element ED3 may include a third lower electrode LE3, a third light-emitting pattern EP3, a third upper electrode UE3, and a third capping electrode CE3.

The first to third lower electrodes LE1, LE2, and LE3 may be provided as a plurality of patterns. Hereinafter, the first lower electrode LE1 will be mainly described, and description of the first lower electrode LE1 may be equally applied to the second lower electrode LE2 and the third lower electrode LE3.

The first lower electrode LE1 may be located on the conductive pattern CDP to be described later. Specifically, the first lower electrode LE1 may be directly located on a second conductive pattern CDP2 to be described later.

An edge of the first lower electrode LE1 may be covered with the pixel-defining film PDL to be described later. Specifically, an edge of an upper surface of the first lower electrode LE1 and a side surface of the first lower electrode LE1 may be covered with the pixel-defining film PDL. Because the edge of the first lower electrode LE1 is covered with the pixel-defining film PDL, the edge of the first lower electrode LE1 may be insulated.

The first lower electrode LE1 may be a (semi-) transmissive electrode or a reflective electrode. The first lower electrode LE1 may be single-layered or multi-layered. For example, the first lower electrode LE1 may include a first layer and a second layer.

The first layer may include a metal material. For example, the first layer may be a reflective layer formed of silver (Ag), magnesium (Mg), aluminum (Al), platinum (Pt), palladium (Pd), gold (Au), nickel (Ni), neodymium (Nd), iridium (Ir), chromium (Cr), a compound thereof, or the like.

The second layer may be located on the first layer. The second layer may include transparent conductive oxide. For example, the second layer may be a transparent or translucent layer including at least one selected from the group consisting of indium tin oxide (ITO), indium zinc oxide (IZO), indium gallium zinc oxide (IGZO), zinc oxide (ZnO), indium oxide (In₂O₃), and aluminum-doped zinc oxide (AZO). According to some embodiments, the second layer may include crystalized transparent conductive oxide, and for example, the transparent conductive oxide may include poly-ITO.

According to some embodiments, the first lower electrode LE1 may further include a third layer below the first layer. The third layer may include transparent conductive oxide. Here, the third layer and the second layer may include the same material or different materials.

The first to third light-emitting patterns EP1, EP2, and EP3 may be each arranged on a corresponding lower electrode among the first to third lower electrodes LE1, LE2, and LE3. Specifically, the first light-emitting pattern EP1 may be located on the first lower electrode LE1, the second light-emitting pattern EP2 may be located on the second lower electrode LE2, and the third light-emitting pattern EP3 may be located on the third lower electrode LE3. According to some embodiments, the first light-emitting pattern EP1 may provide red light, the second light-emitting pattern EP2 may provide green light, and the third light-emitting pattern EP3 may provide blue light.

The first to third light-emitting patterns EP1, EP2, and EP3 may each include an emission layer including a light-emitting material. The first to third light-emitting patterns EP1, EP2, and EP3 may each further include a hole injection layer and/or a hole transport layer located between the emission layer and a corresponding lower electrode among the first to third lower electrodes LE1, LE2, and LE3. In addition, the first to third light-emitting patterns EP1, EP2, and EP3 may each further include an electron transport layer and an electron injection layer located on the emission layer.

The first light-emitting pattern EP1, the second light-emitting pattern EP2, and the third light-emitting pattern EP3 may be respectively arranged in the first light-emitting opening OPE1, the second light-emitting opening OPE2, and the third light-emitting opening OPE3 defined by the pixel-defining film PDL to be described later. Upper surfaces of the first to third lower electrodes LE1, LE2, and LE3 exposed by the first to third light-emitting openings OPE1, OPE2, and OPE3 defined in the pixel-defining film PDL may be respectively covered with the first to third light-emitting patterns EP1, EP2, and EP3.

In addition, the first light-emitting pattern EP1, the second light-emitting pattern EP2, and the third light-emitting pattern EP3 may be arranged covering up to a portion of the pixel-defining film PDL covering edges of the lower electrodes LE1, LE2, and LE3.

The light-emitting patterns EP1, EP2, and EP3 according to the present disclosure may be formed to a uniform thickness because the light-emitting patterns EP1, EP2, and EP3 are located on the conductive pattern CDP. Thus, the light-emitting patterns EP1, EP2, and EP3 may be applied to the display panel DP having high resolution.

The first to third upper electrodes UE1, UE2, and UE3 may be each located on a corresponding light-emitting pattern among the first to third light-emitting patterns EP1, EP2, and EP3. Specifically, the first upper electrode UE1 may be located on the first light-emitting pattern EP1, the second upper electrode UE2 may be located on the second light-emitting pattern EP2, and the third upper electrode UE3 may be located on the third light-emitting pattern EP3.

The first to third upper electrodes UE1, UE2, and UE3 may be each directly arranged covering an upper surface of a corresponding light-emitting pattern among the first to third light-emitting patterns EP1, EP2, and EP3. In addition, the first to third upper electrodes UE1, UE2, and UE3 may each cover at least a portion of a side surface of a corresponding light-emitting pattern among the first to third light-emitting patterns EP1, EP2, and EP3.

The first to third capping electrodes CE1, CE2, and CE3 may be each located on a corresponding upper electrode among the first to third upper electrodes UE1, UE2, and UE3. Specifically, the first capping electrode CE1 may be located on the first upper electrode UE1, the second capping electrode CE2 may be located on the second upper electrode UE2, and the third capping electrode CE3 may be located on the third upper electrode UE3.

The first to third capping electrodes CE1, CE2, and CE3 may be each directly arranged covering an upper surface of a corresponding upper electrode among the first to third upper electrodes UE1, UE2, and UE3. In addition, the first to third capping electrodes CE1, CE2, and CE3 may each cover at least a portion of a side surface of a corresponding upper electrode among the first to third upper electrodes UE1, UE2, and UE3.

The first to third capping electrodes CE1, CE2, and CE3 may prevent or reduce moisture permeation to the first to third upper electrodes UE1, UE2, and UE3 and the first to third light-emitting patterns EP1, EP2, and EP3 during a manufacturing process for the display panel DP. The first to third capping electrodes CE1, CE2, and CE3 may include transparent conductive oxide (TCO).

Because the encapsulation layer TFE is located on the light-emitting element layer EDL, it may be sufficient for the first to third capping electrodes CE1, CE2, and CE3 to be formed to a thickness that enables the first to third capping electrodes CE1, CE2, and CE3 to function to prevent or reduce moisture permeation in the manufacturing process for the display panel DP. The first to third capping electrodes CE1, CE2, and CE3 may function to prevent or reduce moisture permeation in the manufacturing process if a thickness thereof is at least 200 Å (or about 200 Å). For example, in a case in which the first to third capping electrodes CE1, CE2, and CE3 are formed of indium tin oxide (ITO), a thickness thereof may be at least 200 Å (or about 200 Å). In a case in which the first to third capping electrodes CE1, CE2, and CE3 are formed of indium zinc oxide (IZO), a thickness thereof may be 500 Å (or about 500 Å).

In addition, the first to third capping electrodes CE1, CE2, and CE3 may each electrically connect a corresponding upper electrode among the first to third upper electrodes UE1, UE2, and UE3 and an auxiliary electrode AE to be described later.

The pixel-defining film PDL may be located on the circuit layer CL.

In a plan view, the pixel-defining film PDL may be arranged to surround each conductive pattern CDP. The pixel-defining film PDL may correspond to the non-light-emitting region NPXA. The pixel-defining film PDL may include the first to third light-emitting openings OPE1, OPE2, and OPE3 defining the first to third light-emitting regions PXA-R, PXA-G, and PXA-B.

The pixel-defining film PDL may be located on the circuit layer CL which is exposed because the conductive pattern CDP to be described later is not located thereon. The pixel-defining film PDL may be located on a side surface of the conductive pattern CDP. That is, the pixel-defining film PDL may be directly located on an upper surface of the circuit layer CL and the side surface of the conductive pattern CDP while covering from the upper surface of the circuit layer CL up to the side surface of the conductive pattern CDP.

In addition, the pixel-defining film PDL may cover edges of the first to third lower electrodes LE1, LE2, and LE3 located on the conductive pattern CDP.

Specifically, the pixel-defining film PDL may cover side surfaces and edge portions of upper surfaces of the first to third lower electrodes LE1, LE2, and LE3. Because the pixel-defining film PDL covers the edges of the first to third lower electrodes LE1, LE2, and LE3, the edges of the first to third lower electrodes LE1, LE2, and LE3 may be insulated.

The pixel-defining film PDL may include an inorganic insulating material, and may include, for example, silicon nitride (SiNₓ). It may be sufficient for the pixel-defining film PDL to have a thickness that enables the pixel-defining film PDL to insulate the edges of the first to third lower electrodes LE1, LE2, and LE3. For example, in a case in which the pixel-defining film PDL is formed of silicon nitride, a thickness of the pixel-defining film PDL may be 2000 Å (or about 2000 Å).

The conductive pattern CDP may be located on the circuit layer CL. A portion, of the circuit layer CL, on which the conductive pattern CDP is not located may be covered with the pixel-defining film PDL. The first to third light-emitting elements ED1, ED2, and ED3 described above may be located on the conductive pattern CDP. The pixel-defining film PDL may be directly located on the side surface of the conductive pattern CDP, and the side surface of the conductive pattern CDP may be covered with the pixel-defining film PDL.

The conductive pattern CDP may have a multi-layered structure. As shown in FIG. 6, the conductive pattern CDP may include a first conductive pattern CDP1 located on the circuit layer CL, and a second conductive pattern CDP2 located on the first conductive pattern CDP1. A thickness of the second conductive pattern CDP2 may be greater than a thickness of the first conductive pattern CDP1.

In a plan view, a side surface of the second conductive pattern CDP2 may protrude further than a side surface of the first conductive pattern CDP1. In the second conductive pattern CDP2, a portion protruding further than the side surface of the first conductive pattern CDP1 may be defined as a tip portion of the conductive pattern CDP.

The first conductive pattern CDP1 and the second conductive pattern CDP2 may each include an inorganic material. The first conductive pattern CDP1 and the second conductive pattern CDP2 may each include an inorganic insulating film or conductive metal. The first conductive pattern CDP1 and the second conductive pattern CDP2 may each include conductive metal. For example, the first conductive pattern CDP1 may include aluminum (Al) or molybdenum (Mo), and the second conductive pattern CDP2 may include titanium (Ti). However, a material included in the first conductive pattern CDP1 and the second conductive pattern CDP2 is not limited thereto.

In an etching process for forming the conductive pattern CDP, an etch rate of the first conductive pattern CDP1 may be greater than an etch rate of the second conductive pattern CDP2. That is, the first conductive pattern CDP1 may include a material having higher etching selectivity than the second conductive pattern CDP2.

Unlike the illustration in FIG. 6, the conductive pattern CDP may further include a third conductive pattern located under the first conductive pattern CDP1. The above description of the second conductive pattern CDP2 may be applied to the third conductive pattern.

The encapsulation layer TFE may encapsulate the light-emitting element layer EDL. The encapsulation layer TFE may cover the light-emitting elements ED1, ED2, and ED3. The encapsulation layer TFE may be a thin-film encapsulation layer. The encapsulation layer TFE may be one layer or a plurality of layers that are stacked. The encapsulation layer TFE may include at least one insulating layer.

The encapsulation layer TFE may include at least one inorganic film and at least one organic film. The encapsulation layer TFE may include a first inorganic encapsulation film IEN1, an organic encapsulation film OEN, and a second inorganic encapsulation film IEN2.

The first inorganic encapsulation film IEN1 and the second inorganic encapsulation film IEN2 protect the light-emitting element layer EDL from moisture and oxygen. The first inorganic encapsulation film IEN1 and the second inorganic encapsulation film IEN2 may include silicon nitride, silicon oxynitride, silicon oxide, titanium oxide, aluminum oxide, or the like, and are not particularly limited thereto.

The organic encapsulation film OEN protects the light-emitting element layer EDL from foreign substances such as dust particles. The organic encapsulation film OEN may include an acrylic compound, an epoxy-based compound, etc. The organic encapsulation film OEN may include a photopolymerizable organic material and is not particularly limited. In addition, the organic encapsulation film OEN may cover and planarize a step formed by the light-emitting element layer EDL located below.

The first inorganic encapsulation film IEN1 may be arranged to surround the conductive pattern CDP in a plan view. The first inorganic encapsulation film IEN1 may be arranged to surround the light-emitting elements ED1, ED2, and ED3 in a plan view. That is, the first inorganic encapsulation film IEN1 may be arranged to surround the conductive pattern CDP and the light-emitting elements ED1, ED2, and ED3 located on the conductive pattern CDP. The first inorganic encapsulation film IEN1 may be arranged to overlap the pixel-defining film PDL in a plan view. The first inorganic encapsulation film IEN1 may be located in the non-light-emitting region NPXA.

The first inorganic encapsulation film IEN1 may be located on the pixel-defining film PDL. The first inorganic encapsulation film IEN1 may be located in a region in which the conductive pattern CDP is not located with the pixel-defining film PDL therebetween.

The first inorganic encapsulation film IEN1 may cover a portion of the pixel-defining film PDL not covered with the light-emitting patterns EP1, EP2, and EP3. The first inorganic encapsulation film IEN1 may cover a portion of the light-emitting patterns EP1, EP2, and EP3 not covered with the upper electrodes UE1, UE2, and UE3. The first inorganic encapsulation film IEN1 may cover a portion of the upper electrodes UE1, UE2, and UE3 not covered with the capping electrodes CE1, CE2, and CE3. The first inorganic encapsulation film IEN1 may cover edges of the capping electrodes CE1, CE2, and CE3. Specifically, the first inorganic encapsulation film IEN1 may cover edges of upper surfaces and side surfaces of the capping electrodes CE1, CE2, and CE3.

An upper surface of the first inorganic encapsulation film IEN1 may include a curved surface that is convex in a third direction DR3 in a cross-sectional view. However, the upper surface of the first inorganic encapsulation film IEN1 is not limited thereto and may be a flat surface.

The encapsulation layer TFE may further include the auxiliary electrode AE. The auxiliary electrode AE may be located on the light-emitting elements ED1, ED2, and ED3 and the first inorganic encapsulation film IEN1. Specifically, the auxiliary electrode AE may be directly arranged, in an integrated form, on the capping electrodes CE1, CE2, and CE3 and the first inorganic encapsulation film IEN1 and electrically connected to the upper electrodes UE1, UE2, and UE3.

The auxiliary electrode AE may include transparent conductive oxide (TCO). The auxiliary electrode AE may include the same material as the capping electrodes CE1, CE2, and CE3.

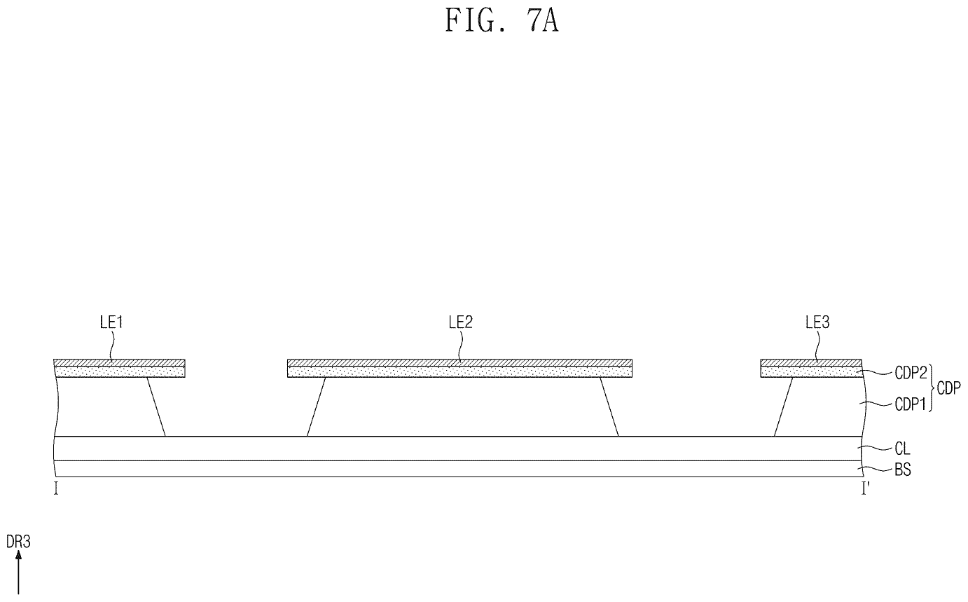

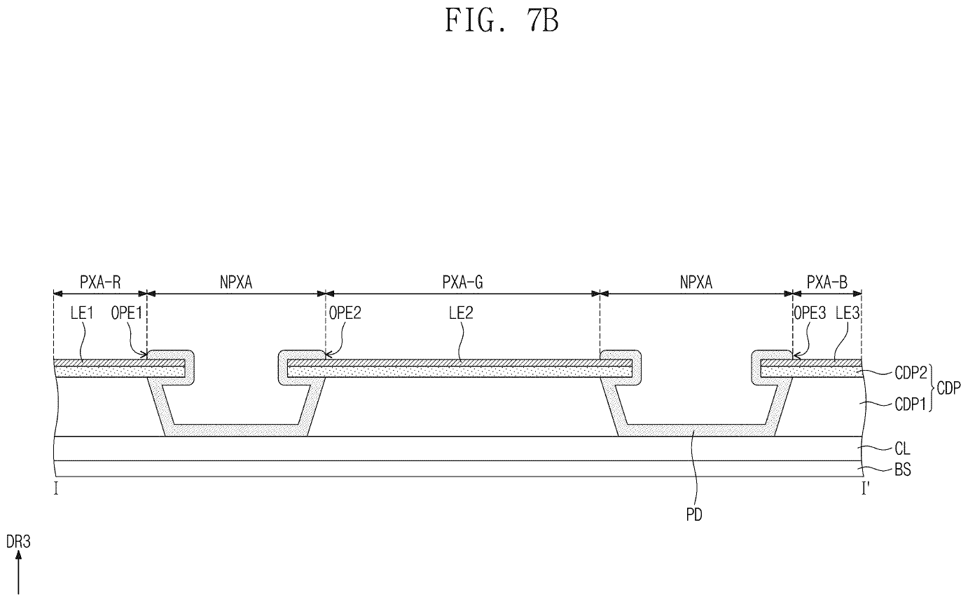

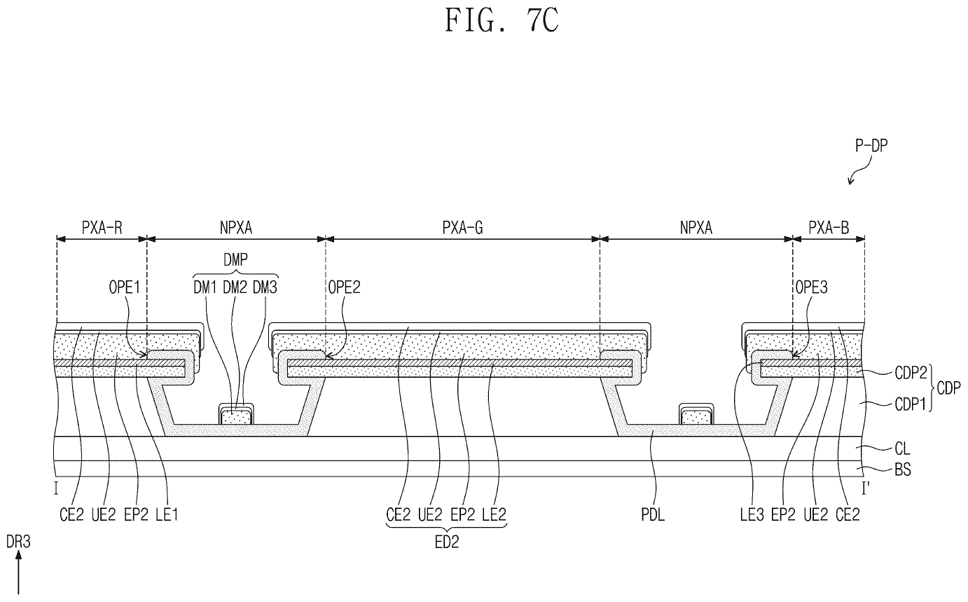

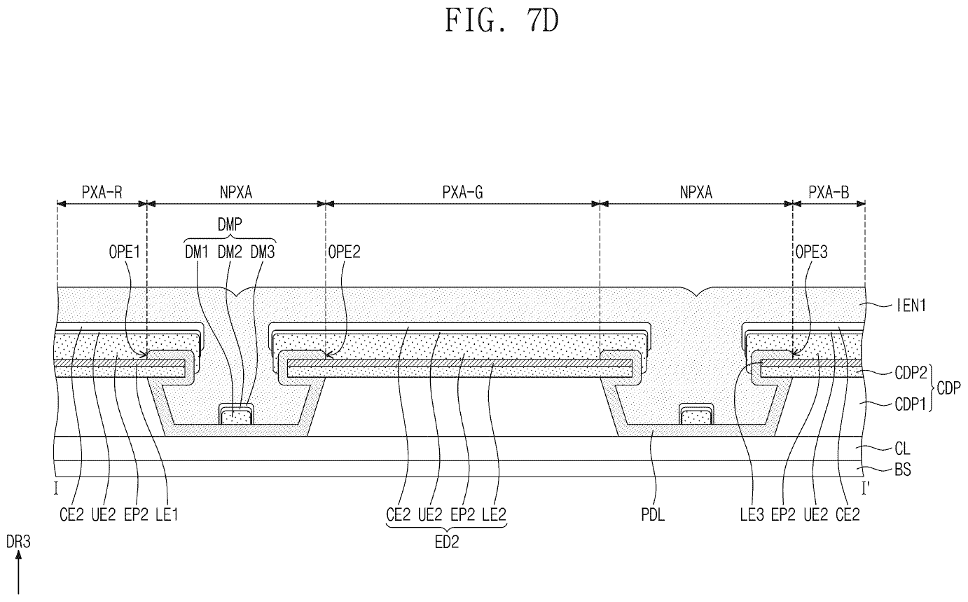

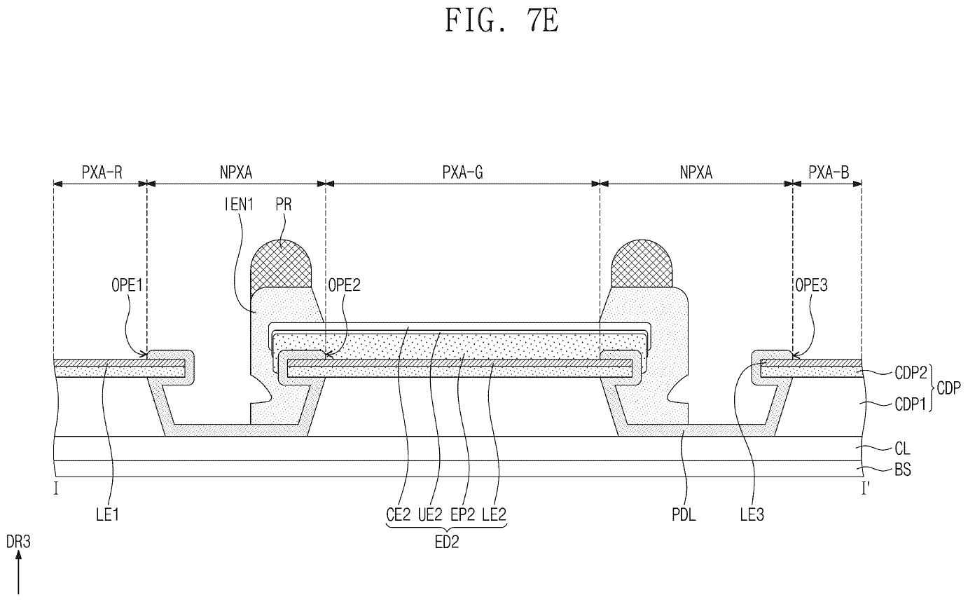

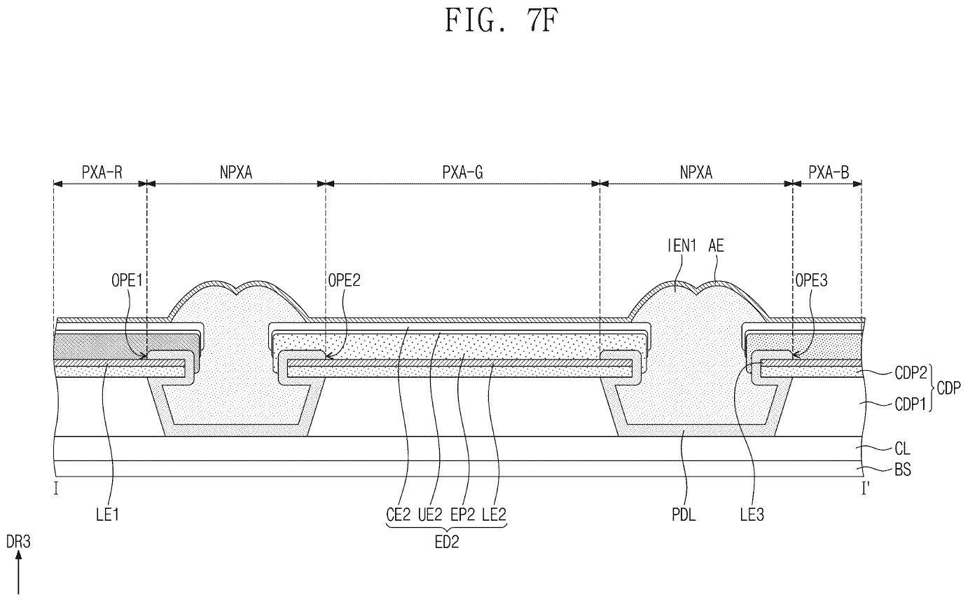

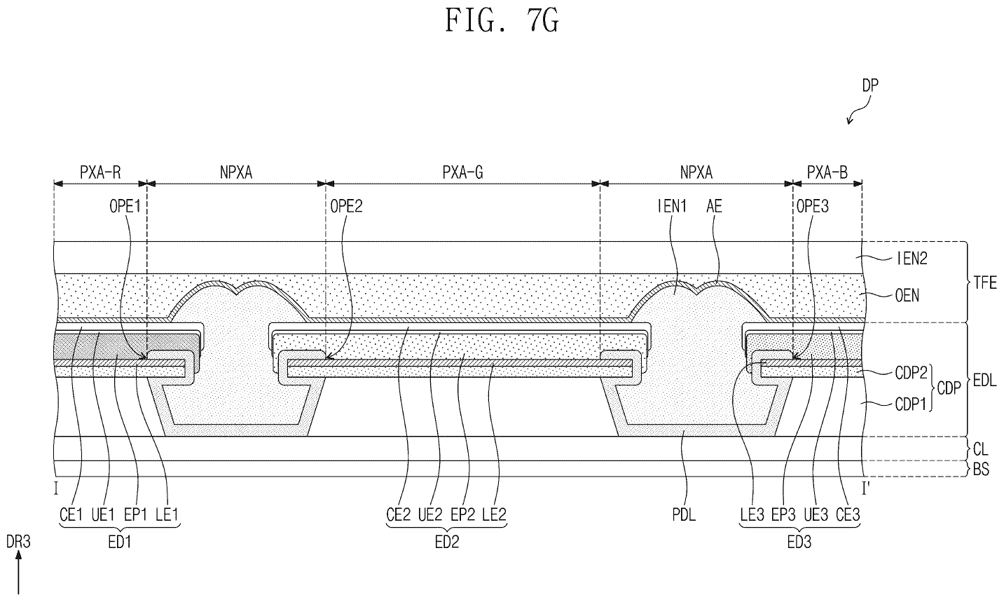

FIGS. 7A to 7G each are a cross-sectional view illustrating a step of a manufacturing method of the display panel DP (see FIG. 6) according to some embodiments of the present disclosure. In FIGS. 7A to 7G, the same content as the above description made with reference to FIG. 6 may be applied to the same component.

The manufacturing method of the display panel DP (see FIG. 6) according to some embodiments of the present disclosure includes providing a preliminary display panel P-DP, forming a first inorganic encapsulation film IEN1, and forming an auxiliary electrode AE.

Referring to FIGS. 7A to 7C, the manufacturing method of the display panel DP (see FIG. 6) according to some embodiments may include providing the preliminary display panel P-DP including a conductive pattern CDP and a light-emitting element ED2 located on the conductive pattern CDP.

FIG. 7A illustrates patterning the conductive pattern CDP and first to third lower electrodes LE1, LE2, and LE3. The conductive pattern CDP and the first to third lower electrode LE1, LE2, and LE3 may be patterned by forming each of a conductive layer and an electrode layer and then selectively etching the conductive layer and the electrode layer.

The conductive layer and the electrode layer may be formed through a sputtering process. The conductive layer may be formed on a circuit layer. The conductive layer may include a first conductive layer and a second conductive layer. The first conductive layer may be formed on the circuit layer, and the second conductive layer may be formed on the first conductive layer. For example, the first conductive layer may include aluminum, and the second conductive layer may include titanium. The electrode layer may be formed on the conductive layer. The electrode layer may be formed of a single layer or multiple layers. For example, the electrode layer may be formed of a multi-layered structure of silver/indium tin oxide.

The electrode layer may be photoresist-patterned and then patterned through wet etching. The first to third lower electrodes LE1, LE2, and LE3 may be formed by patterning the electrode layer. The conductive layer may be patterned through dry etching. The conductive pattern CDP may be formed by patterning the conductive layer. Because an etch rate of the first conductive layer is greater than an etch rate of the second conductive layer, a tip structure in which a side surface of a second conductive pattern CDP2 protrudes further than a side surface of a first conductive pattern CDP1 may be formed.

FIG. 7B illustrates forming a pixel-defining film PDL. The pixel-defining film PDL may be formed by depositing an inorganic film and then patterning the inorganic film through a photoresist process. The inorganic film may include, for example, silicon nitride. The inorganic film may be deposited through a chemical vapor deposition (CVD) process.

The pixel-defining film PDL may include first to third light-emitting openings OPE1, OPE2, and OPE3 defining first to third light-emitting regions PXA-R, PXA-G, and PXA-B. The pixel-defining film PDL may be formed to cover an upper surface of a circuit layer CL, which is exposed because the conductive pattern CDP is not located thereon, and a side surface of the conductive pattern CDP. In addition, the pixel-defining film PDL may be formed to cover up to side surfaces and edge portions of upper surfaces of the first to third lower electrodes LE1, LE2, and LE3. The first to third light-emitting regions PXA-R, PXA-G, and PXA-B and a non-light-emitting region NPXA may be defined by the pixel-defining film PDL. The pixel-defining film PDL may be formed corresponding to the non-light-emitting region NPXA.

FIG. 7C illustrates forming the light-emitting element ED2. FIG. 7C illustrates only forming a second light-emitting element ED2, but a first light-emitting element ED1 and a third light-emitting element ED3 may be also formed through the same process.

A light-emitting pattern EP2 may be deposited on the first to third lower electrodes LE1, LE2, and LE3. An upper electrode UE2 may be deposited on the light-emitting pattern EP2. A capping electrode CE2 may be deposited on the upper electrode UE2. The light-emitting pattern EP2 and the upper electrode UE2 may be deposited through a thermal evaporation process. The capping electrode CE2 may be deposited through a sputtering process. The capping electrode CE2 may be formed covering at least a portion of a side surface of the light-emitting pattern EP2. The capping electrode CE2 may be formed covering at least a portion of a side surface and an upper surface of the upper electrode UE2.

The light-emitting pattern EP2, the upper electrode UE2, and the capping electrode CE2 may be deposited in all of the light-emitting regions PXA-R, PXA-G, and PXA-B and the non-light-emitting region NPXA, and thus may be also deposited on the pixel-defining film PDL in a region in which the conductive pattern CDP is not located. Light-emitting pattern EP2, upper electrode UE2, and capping electrode CE2 materials deposited in the region in which the conductive pattern CDP is not located may be defined as a dummy pattern DMP. The dummy pattern DMP may include a first dummy DM1, a second dummy DM2, and a third dummy DM3. The first dummy DM1 may correspond to the same material as the light-emitting pattern EP2, the second dummy DM2 may correspond to the same material as the upper electrode UE2, and the third dummy DM3 may correspond to the same material as the capping electrode CE2.

The light-emitting pattern EP2 may be formed on the conductive pattern CDP, and thus may be formed to a uniform thickness. Accordingly, the light-emitting pattern EP2 may be applied to the display panel DP (see FIG. 6) having high resolution.

Referring to FIGS. 7D to 7F, the manufacturing method of the display panel DP (see FIG. 6) according to some embodiments may include the forming of the first inorganic encapsulation film IEN1 and the forming of the auxiliary electrode AE.

FIG. 7D illustrates depositing an inorganic layer so as to form the first inorganic encapsulation film IEN1. The inorganic layer may be formed through a chemical vapor deposition process. The inorganic layer may be blanket deposited.

FIG. 7E illustrates patterning so as to form the first light-emitting element ED1 and the third light-emitting element ED3. In the patterning process, a half-tone mask may be applied. In the patterning process, moisture permeation to the second light-emitting element ED2 may be prevented or reduced by the capping electrode CE2.

The inorganic layer in the first to third light-emitting regions PXA-R, PXA-G, and PXA-B and the non-light-emitting region NPXA around the first and third light-emitting regions PXA-R and PXA-B may be removed through a dry etching process. The capping electrode CE2 and the upper electrode UE2 in the non-light-emitting region NPXA around the first and third light-emitting regions PXA-R and PXA-B may be removed through a wet etching process. The light-emitting pattern EP2 in the non-light-emitting region NPXA around the first and third light-emitting regions PXA-R and PXA-B may be removed through a dry etching process.

The dummy pattern DMP may be also removed in the same process described above. Thereafter, the first and third light-emitting elements ED1 and ED3 shown in FIG. 7F may be formed through such steps described with reference to FIGS. 7C to 7E.

FIG. 7F illustrates the forming of the auxiliary electrode AE. The auxiliary electrode AE may be integrally formed on the first to third light-emitting elements ED1, ED2, and ED3 and the first inorganic encapsulation film IEN1. The auxiliary electrode AE may be deposited through a sputtering process. The auxiliary electrode AE may include transparent conductive oxide. The auxiliary electrode AE may be integrally formed, directly located on first to third capping electrodes CE1, CE2, and CE3, and electrically connect first to third upper electrodes UE1, UE2, and UE3.

Referring to FIG. 7G, the manufacturing method of the display panel DP (see FIG. 6) according to some embodiments may further include forming an organic encapsulation film OEN and a second inorganic encapsulation film IEN2. The organic encapsulation film OEN may planarize a step formed by the first inorganic encapsulation film IEN1 and a light-emitting element layer EDL. The organic encapsulation film OEN may prevent or reduce introduction of foreign substances or contaminants such as dust particles from the outside. The second inorganic encapsulation film IEN2 may prevent or reduce introduction of contaminants such as moisture or oxygen from the outside.

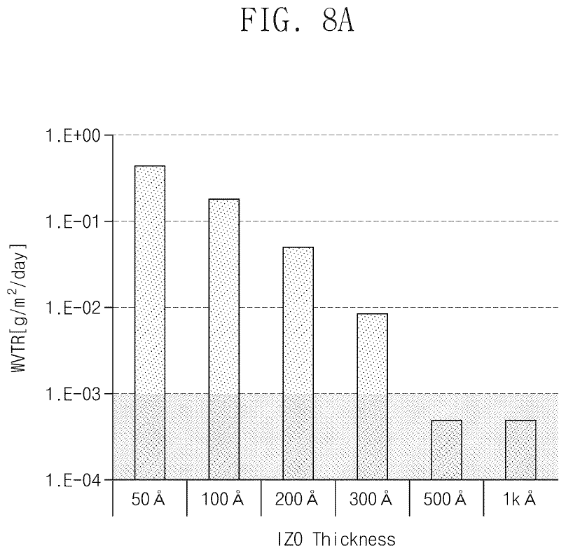

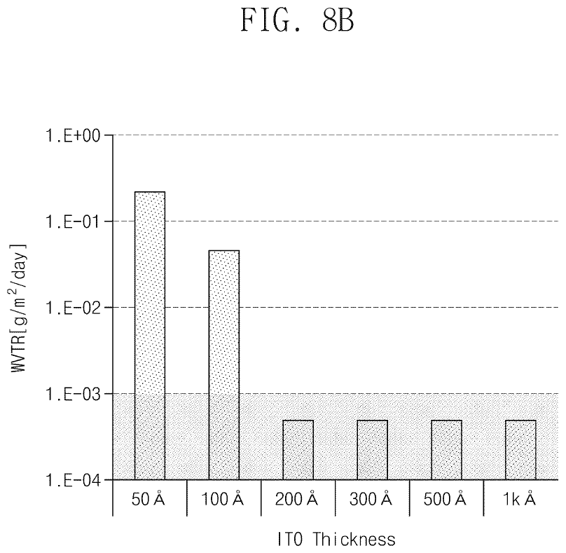

FIGS. 8A and 8B each are a graph showing an evaluation result of moisture permeation characteristics of the capping electrodes CE1, CE2, and CE3 (see FIG. 6) according to some embodiments of the present disclosure.

FIG. 8A is a graph showing a result obtained by forming, on a glass substrate, a layer of indium zinc oxide (IZO) to respective thicknesses of 50 Å (or about 50 Å), 100 Å (or about 100 Å), 200 Å (or about 200 Å), 300 Å (or about 300 Å), 500 Å (or about 500 Å), and 1 k Å (or about 1 k Å) and measuring water vapor transmission rate (WVTR) thereof.

In a case in which a layer of indium zinc oxide (IZO) is formed to a thickness of at least 500 Å (or about 500 Å), the layer of indium zinc oxide (IZO) may have water vapor transmission rate equal to or lower than 1.0E-3 (or about 1.0E-3). Accordingly, in a case in which the capping electrodes CE1, CE2, and CE3 (see FIG. 6) of the present disclosure are formed of indium zinc oxide (IZO), the capping electrodes CE1, CE2, and CE3 with a thickness of at least 500 Å (or about 500 Å) may be applied so as to prevent or reduce moisture permeation during a manufacturing process for the display panel DP (see FIG. 6).

FIG. 8B is a graph showing a result obtained by forming, on a glass substrate, a layer of indium tin oxide (ITO) to respective thicknesses of 50 Å (or about 50 Å), 100 Å (or about 100 Å), 200 Å (or about 200 Å), 300 Å (or about 300 Å), 500 Å (or about 500 Å), and 1 k Å (or about 1 k Å) and measuring water vapor transmission rate (WVTR) thereof.

In a case in which a layer of indium tin oxide (ITO) is formed to a thickness of at least 200 Å (or about 200 Å), the layer of indium tin oxide (ITO) may have water vapor transmission rate equal to or lower than 1.0E-3 (or about 1.0E-3). Accordingly, in a case in which the capping electrodes CE1, CE2, and CE3 (see FIG. 6) of the present disclosure are formed of indium tin oxide (ITO), the capping electrodes CE1, CE2, and CE3 with a thickness of at least 200 Å (or about 200 Å) may be applied so as to prevent or reduce moisture permeation during the manufacturing process for the display panel DP (see FIG. 6).

According to the above descriptions, a display panel capable of providing high resolution and having relatively improved reliability may be provided.

In addition, a manufacturing method of a display panel having relatively improved processability and reliability in that a light-emitting pattern may be formed to a relatively uniform thickness and moisture permeation may be prevented or reduced during a process may be provided.

Although description has been made with reference to embodiments of the present disclosure, it is understood that the present disclosure should not be limited to these embodiments, but various changes and modifications may be made by one ordinary skilled in the art within the spirit and scope of the present disclosure as hereinafter claimed. Therefore, the technical scope of the present disclosure is not limited to the contents described in the detailed description of the specification, but should be determined by the accompanying claims.

What is claimed is:

1. A display panel comprising:
a base layer;
a circuit layer on the base layer;
a light-emitting element layer on the circuit layer; and
an encapsulation layer on the light-emitting element layer,
wherein the light-emitting element layer includes
a conductive pattern on the circuit layer,
a first electrode on the conductive pattern, and
a light-emitting pattern on the first electrode, and
the encapsulation layer includes a first inorganic encapsulation film surrounding the conductive pattern in a plan view.

2. The display panel of claim 1, wherein the light-emitting element layer further comprises a pixel-defining film between the circuit layer and the first inorganic encapsulation film, and
the pixel-defining film covers an upper surface of the circuit layer, which is exposed because the conductive pattern is not located thereon, and a side surface of the conductive pattern.

3. The display panel of claim 2, wherein the pixel-defining film extends covering from the side surface of the conductive pattern to a side surface of the first electrode.

4. The display panel of claim 1, wherein the light-emitting element layer further comprises a second electrode on the light-emitting pattern.

5. The display panel of claim 4, wherein the light-emitting element layer further comprises a capping electrode directly on and electrically connected to the second electrode, and
the capping electrode includes transparent conductive oxide (TCO).

6. The display panel of claim 5, wherein the capping electrode comprises indium zinc oxide (IZO) or indium tin oxide (ITO).

7. The display panel of claim 5, wherein the encapsulation layer further comprises an auxiliary electrode covering the capping electrode and the first inorganic encapsulation film and arranged in an integrated form,
the capping electrode comprises a plurality of capping electrodes,
the plurality of capping electrodes is electrically connected to each other by the auxiliary electrode, and
the auxiliary electrode includes transparent conductive oxide (TCO).

8. The display panel of claim 7, wherein the encapsulation layer further comprises:
an organic encapsulation film on the auxiliary electrode; and
a second inorganic encapsulation film on the organic encapsulation film.

9. The display panel of claim 4, wherein in a plan view, the conductive pattern, the first electrode, the light-emitting pattern, and the second electrode overlap.

10. The display panel of claim 1, wherein the first inorganic encapsulation film covers a side surface of the conductive pattern, a side surface of the first electrode, and a side surface of the light-emitting pattern.

11. The display panel of claim 1, wherein the conductive pattern comprises a first conductive layer on the circuit layer and a second conductive layer on the first conductive layer, and
a side surface of the second conductive layer protrudes further than a side surface of the first conductive layer.

12. The display panel of claim 11, wherein the first conductive layer comprises aluminum (Al), and
the second conductive layer comprises titanium (Ti).

13. The display panel of claim 1, wherein the first electrode comprises a first layer on the conductive pattern and a second layer on the first layer,
the first layer includes silver (Ag) or aluminum (Al), and
the second layer includes indium tin oxide (ITO) or indium zinc oxide (IZO).

14. An electronic device comprising:
a display module;
a window on the display module; and
a housing under the display module,
wherein a display module comprising:
a base layer including a plurality of light-emitting regions and a non-light-emitting region surrounding the plurality of light-emitting regions;
a light-emitting element layer including a conductive pattern in the plurality of light-emitting regions, a light-emitting element on the conductive pattern, and a pixel-defining film in the non-light-emitting region and defining the plurality of light-emitting regions; and
an encapsulation layer including an inorganic encapsulation film in the non-light-emitting region, and an auxiliary electrode integrally in the plurality of light-emitting regions and the non-light-emitting region and electrically connected to the light-emitting element,
wherein the conductive pattern includes a first conductive pattern on the base layer and a second conductive pattern on the first conductive pattern, and a side surface of the second conductive pattern protrudes further than a side surface of the first conductive pattern.

15. A manufacturing method of a display panel, the manufacturing method comprising:
providing a preliminary display panel including a circuit layer, a conductive pattern on the circuit layer, and a light-emitting element on the conductive pattern;
forming an inorganic encapsulation film to surround the conductive pattern and the light-emitting element in a plan view, and
forming an auxiliary electrode on the light-emitting element and the inorganic encapsulation film.

16. The manufacturing method of claim 15, wherein the providing of the preliminary display panel comprises forming a first electrode, a light-emitting pattern, and a second electrode on the conductive pattern.

17. The manufacturing method of claim 16, wherein the providing of the preliminary display panel further comprises forming a capping electrode on the second electrode.

18. The manufacturing method of claim 16, wherein the providing of the preliminary display panel further comprises forming a pixel-defining film defining a pixel region on the circuit layer, and
the pixel-defining film is formed to cover at least a side surface of the first electrode.

19. The manufacturing method of claim 15, wherein the auxiliary electrode is integrally formed.

20. The manufacturing method of claim 15, wherein the conductive pattern comprises a first conductive pattern on the circuit layer and a second conductive pattern on the first conductive pattern, and
a side surface of the second conductive pattern is formed to protrude further than a side surface of the first conductive pattern.
